(19) United States
(12) Patent Application Publication
(10) Pub. No.: US 2011/0220165 A1
(43) Pub. Date: Sep. 15, 2011

(54) THERMOELECTRIC DEVICE INCLUDING THERMOELECTRIC BODY INCLUDING VACANCY CLUSTER

(75) Inventors: Eun-kyung LEE, Seoul (KR); Byoung-lyong CHOI, Seoul (KR); Gyeong S. HWANG, Austin, TX (US)

(73) Assignee: SAMSUNG ELECTRONICS CO., LTD., Suwon-si (KR)

(21) Appl. No.: 13/044,878

(22) Filed: Mar. 10, 2011

(30) Foreign Application Priority Data
Mar. 11, 2010 (KR) 10-2010-0021842

(51) Int. Cl. H01L 35/12; H01L 35/34

(52) U.S. Cl. 136/236.1; 136/239; 438/54; 136/201; 257/E21.211

(57) ABSTRACT

A thermoelectric device includes: a first region; a second region; and a thermoelectric body disposed between the first region and the second region, where the thermoelectric body includes a vacancy.

### CROSS-REFERENCE TO RELATED APPLICATIONS

This application claims priority to Korean Patent Application No. 10-2010-0021842, filed on Mar. 11, 2010, and all the benefits accruing therefrom under 35 U.S.C. §119, the content of which in its entirety is herein incorporated by reference.

### BACKGROUND

1. Field

The general inventive concept relates to a thermoelectric device including a thermoelectric body including vacancy clusters formed therein.

2. Description of the Related Art

A thermoelectric device is a device using thermoelectric conversion. Thermoelectric conversion is conversion of thermal energy into electric energy or vice versa. Electricity is generated when there is a temperature difference between both ends of a thermoelectric material, which is referred to as the Seebeck effect. On the other hand, if a current is applied to the thermoelectric material, a temperature gradient is generated between both ends of the thermoelectric material, which is referred to as the Peltier effect. Thermal energy generated in a computer or an automobile engine may be converted into electric energy using the Seebeck effect, and various cooling systems may be implemented without refrigerant using the Peltier effect. As interests in new energy development, waste energy recovery, environment protection, or the like have increased, a thermoelectric device has also attracted much attention.

The efficiency of a thermoelectric device is determined by the figure of merit ZT coefficient, which is a performance coefficient of a thermoelectric material, and a dimensionless performance parameter. The ZT coefficient may be expressed as follows.

$$ZT = \frac{{S}^{2} σ}{k} T \qquad ( 1 )$$

In Equation (1), the ZT coefficient is proportional to a Seebeck coefficient S of the thermoelectric material and an electric conductivity σ and is inversely proportional to a thermal conductivity k. The Seebeck coefficient S represents a voltage per unit temperature change (dV/dT). The Seebeck coefficient S, the electric conductivity σ, and the thermal conductivity k are interrelated, and thus, they may not be controlled independently of one another. As a result, a thermoelectric device with a substantially large ZT coefficient, or a high-efficiency thermoelectric device, may not be easily implemented.

### SUMMARY

Provided is a thermoelectric device including a thermoelectric body including a vacancy formed therein.

In an embodiment, a thermoelectric device includes: a first region; a second region; and a thermoelectric body disposed between the first region and the second region, where the thermoelectric body includes a vacancy.

The thermoelectric body may include silicon (Si). In addition, the thermoelectric body may include at least one of amorphous silicon and polysilicon.

The thermoelectric body may include at least one of glass, germanium (Ge), SiGe, sapphire, quartz and an organic material.

The thermoelectric body may include at least one of an n-type dopant and a p-type dopant. The at least one of the n-type and the p-type dopant may include at least one of arsenic (As), phosphorus (P), boron (B), aluminium (Al), gallium (Ga), antimony (Sb), indium (In) and silicon (Si).

The thermoelectric device may further include a first electrode disposed between the first region and the second region; and a second electrode disposed between the second region and the thermoelectric body.

In an embodiment, a thermoelectric device array includes: a plurality of first regions; a plurality of second regions; and a plurality of thermoelectric bodies. The plurality of thermoelectric bodies includes: a plurality of first thermoelectric bodies doped with an n-type dopant; and a plurality of second thermoelectric bodies doped with a p-type dopant, where the plurality of first thermoelectric bodies and the plurality of second thermoelectric bodies are alternately disposed between the plurality of first regions and the plurality of second regions, and where the plurality of thermoelectric bodies includes a plurality of vacancies formed therein.

### BRIEF DESCRIPTION OF THE DRAWINGS

These and/or other aspects will become apparent and more readily appreciated from the following description of the embodiments, taken in conjunction with the accompanying drawings of which:

FIG. 1 is a cross-sectional view of an embodiment of a thermoelectric device including a thermoelectric body according to the present invention;

FIGS. 2A and 2B are partial cross-sectional views of an alternative embodiment of a thermoelectric device including nanorod-shaped thermoelectric bodies according to an embodiment of the present invention;

FIGS. 3A and 3B are partial cross-sectional views of an alternative embodiment of a thermoelectric device including thermoelectric bodies disposed on a silicon-on-insulator (“SOI”) substrate according to the present invention; and

FIG. 4 is a schematic side view of an embodiment of a thermoelectric device array according to the present invention.

### DETAILED DESCRIPTION

Embodiments now will be described more fully hereinafter with reference to the accompanying drawings, in which embodiments are shown. These embodiments may, however, be embodied in many different forms and should not be construed as limited to the embodiments set forth herein. Rather, these embodiments are provided so that this disclosure will be thorough and complete, and will fully convey the scope of the disclosure to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the disclosure.

All methods described herein can be performed in a suitable order unless otherwise indicated herein or otherwise clearly contradicted by context. The use of any and all examples, or exemplary language (e.g., “such as”), is intended merely to better illustrate the disclosure and does not pose a limitation on the scope thereof unless otherwise claimed. No language in the specification should be construed as indicating any non-claimed element as essential to the practice of the embodiments as used herein.

Hereinafter, the embodiments will be described in detail with reference to the accompanying drawings.

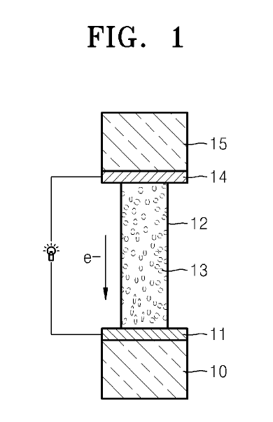

FIG. 1 is a cross-sectional view of an embodiment of a thermoelectric device including a thermoelectric body 12 according to the present invention.

Referring to FIG. 1, the thermoelectric device includes the thermoelectric body 12, in which vacancies 13 are formed therein. The thermoelectric body 12 is disposed between a first region 10 and a second region 15. A first electrode 11 may be disposed between the thermoelectric body 12 and the first region 10, and a second electrode 14 may be disposed between the thermoelectric body 12 and the second region 15.

The first region 10 and the second region 15 may have different temperatures. In an embodiment, a temperature of the first region 10 may be higher than a temperature of the second region 15. In another embodiment, a temperature of the first region 10 may be lower than a temperature of the second region 15. When the thermoelectric device is used as a cooler, if there is no temperature difference between the first region 10 and the second region 15, the temperature difference may be generated by supplying power from an external power source.

The first electrode 11 and the second electrode 14 may include a material that is used in a general semiconductor device, such as a metal or a conductive metal oxide, for example.

The thermoelectric body 12 may include silicon (Si). In an embodiment, the thermoelectric body 12 may be formed of crystalline Si, amorphous Si, poly-Si, or the like. In an alternative embodiment, the thermoelectric body 12 may be formed of glass, germanium (Ge), SiGe, sapphire, quartz, a polymer, or an organic material such as polyvinyl chloride (“PVC”) or polyvinyl alcohol (“PVA”), for example. The thermoelectric body 12 may be doped with various materials. In an embodiment, the thermoelectric body 12 may have a various shape, for example, a rod, wire or a ribbon shape, but not being limited thereto.

A plurality of vacancies, e.g., a cluster of the vacancies 13, is formed in the thermoelectric body 12. The vacancies 13 increases a phonon scattering effect in the thermoelectric body 12 to reduce a thermal conductivity, which will be described in greater detail later.

When there is a temperature difference between the first region 10 and the second region 15, flow of electrons or holes may be induced in the thermoelectric body 12. In an embodiment, the thermoelectric body 12 may be doped with a dopant. As the thermal conductivity of the thermoelectric body 12 is reduced, and as the electric conductivity is increased, performance coefficients of the thermoelectric body 12 may be increased. In such an embodiment, in which the vacancies 13 are formed in the thermoelectric body 12, phonon scattering occurs, and thermal conductivity of the thermoelectric body 12 is thereby substantially reduced.

The vacancies 13 may be formed by doping the thermoelectric body 12 with a dopant. In such an embodiment, the dopant may be an n-type or p-type dopant. In an embodiment, the dopant may be arsenic (As), phosphorus (P), boron (B), aluminium (Al), gallium (Ga), antimony (Sb), indium (In), silicon (Si), or the like, but not being limited thereto. In an embodiment, the thermoelectric body 12 may be doped with the dopant having a high concentration equal to or greater than 10¹⁸ atoms per cubed centimeter. When the thermoelectric body 12 is doped with the dopant, a doping energy may be set to have various ranges to uniformly distribute the vacancies 13, and thus a doping depth, in which the dopant is doped in the thermoelectric body 12, may be determined. The dopant may be used to form the vacancies 13 in the thermoelectric body 12. In an embodiment, a heat-treatment process, which activates the dopant, may be performed to improve the electric conductivity of the thermoelectric body 12.

When the dopant is doped in the thermoelectric body 12, a material constituting the thermoelectric body 12 is affected by the dopant. Atoms may be deintercalated from a lattice of the material of the thermoelectric body 12, thereby forming the vacancies 13 in the thermoelectric body 12. In an embodiment, when Si is used to form the thermoelectric body 12 and Si is doped with the dopant, Si atoms may be deintercalated to an interstitial position, and may be moved to an interface. When the vacancies 13 are formed in the thermoelectric body 12, the electric conductivity of the thermoelectric body 12 may increase due to the dopant. However, when the number of the vacancies 13 in the thermoelectric body 12 increases, phonon scattering may occur. As a result, the vacancies 13 may be further formed by doping the thermoelectric body 12 with the dopant, thereby reducing the thermal conductivity of the thermoelectric body 12 while increasing the electric conductivity of the thermoelectric body 12 to increase the thermal efficiency of the thermoelectric device.

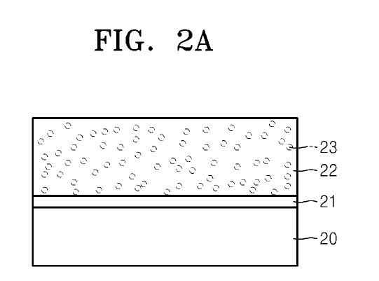

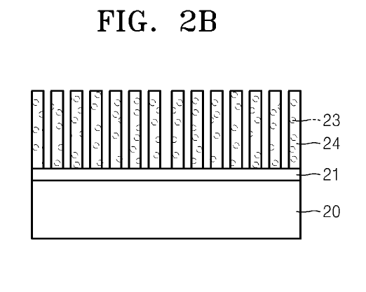

FIGS. 2A and 2B are partial cross-sectional views of an alternative embodiment of a thermoelectric device including nanorod-shaped thermoelectric bodies 24 according to the present invention.

Referring to FIG. 2A, an electrode layer 21 is disposed on a substrate 20. A thermoelectric material 22 is disposed on the electrode layer 21. An n-type or p-type dopant is doped in the thermoelectric material 22 to form vacancies 23. When the thermoelectric material 22 is doped with the dopant, the dopant may be doped by various implantation energies, to uniformly distribute the dopant in the thermoelectric material 22 according to a depth of the thermoelectric material 22. In an embodiment, the kind of dopant may vary according to a position of a portion of the thermoelectric material 22, which is to be doped with the dopant. In an embodiment, the n-type dopant may be doped in a predetermined portion of the thermoelectric material 22, and the p-type dopant may be doped in another portion of the thermoelectric material 22.

Referring to FIG. 2B, each of thermoelectric bodies 24 may have a nanorod shape formed by etching the thermoelectric material 22 including the vacancies 23 formed therein using, for example, a lithography operation. In an embodiment, a dopant with a desired polarity may be doped in a corresponding thermoelectric body 24 by controlling a doping operation.

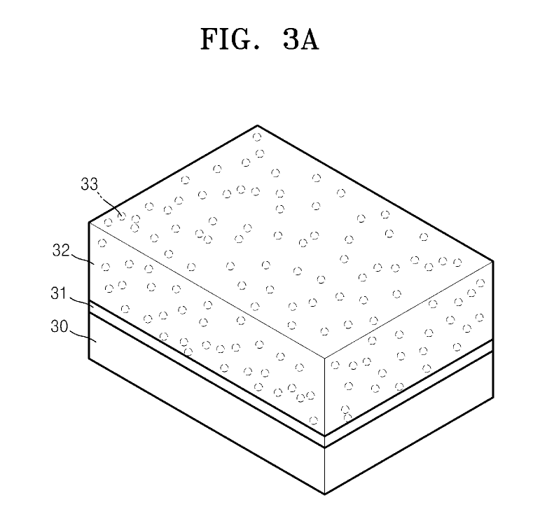

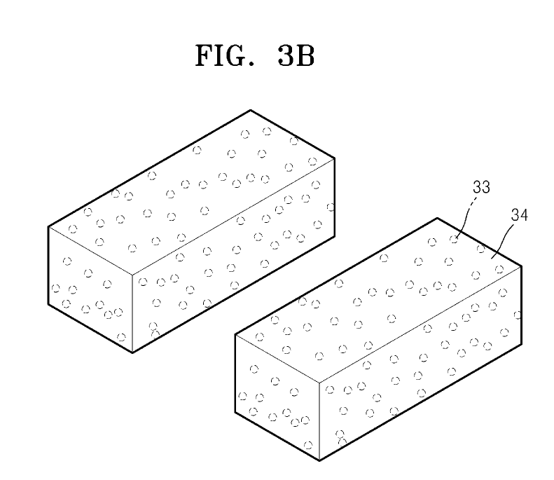

FIGS. 3A and 3B are partial cross-sectional views of an alternative embodiment of a thermoelectric device including thermoelectric bodies 34 disposed on a silicon-on-insulator (“SOI”) substrate according to the present invention. Referring to FIGS. 3A and 3B, the SOI substrate includes an insulating layer 31 disposed on a substrate 30, and a Si layer 32 disposed on the insulating layer 31. The Si layer 32 may be doped with an n-type or p-type dopant, and the vacancies 33 are thereby formed. Then, the thermoelectric bodies 34 may be formed by cutting the Si layer 32 including the vacancies 33 in a desired shape, for example, a ribbon shape.

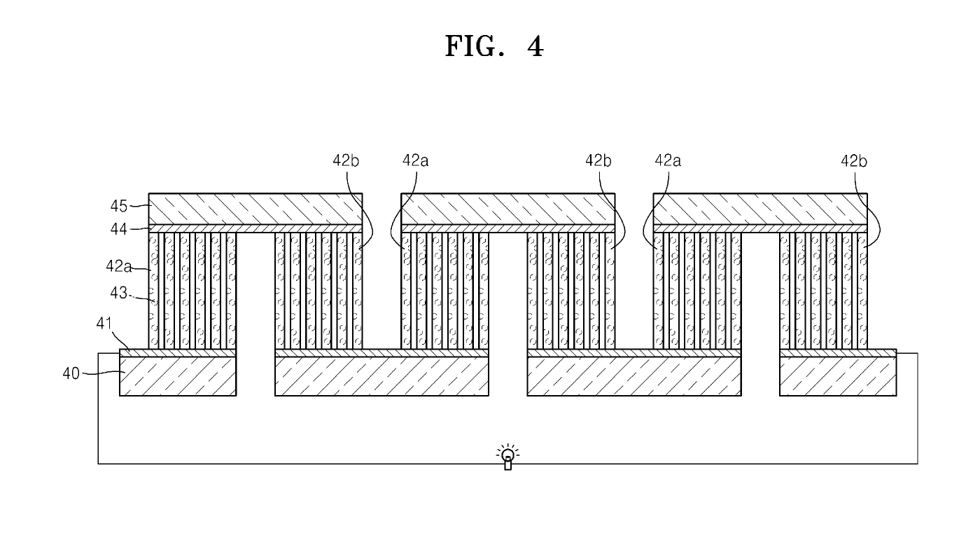

FIG. 4 is a schematic side view of an embodiment of a thermoelectric device array according to the present invention. Referring to FIG. 4, the thermoelectric device array includes a plurality of first regions 40 and a plurality of second regions 45. Thermoelectric bodies, e.g., a plurality of first thermoelectric bodies 42a and a plurality of second thermoelectric bodies 42b, are formed between the first regions 40 and the second regions 45. First electrodes 41 are disposed between the thermoelectric bodies 42a and 42b, and the first regions 40. Second electrodes 44 are disposed between the thermoelectric bodies 42a and 42b, and the second regions 45. Vacancies 43 may be formed in the thermoelectric bodies 42a and 42b. In an embodiment, the first thermoelectric bodies 42a are doped with an n-type dopant, and the second thermoelectric bodies 42b are doped with a p-type dopant. The first and second thermoelectric bodies 42a and 42b may be alternately formed between the first regions 40 and the second regions 45. The first electrodes 41 or the second electrodes 44 may be connected to a capacitor that stores electricity generated by the thermoelectric bodies 42a and 42b, or a load apparatus that consumes the electricity.

According to the one or more of the embodiments of the present invention as described herein, a thermoelectric device include a thermoelectric body including vacancies formed therein, and phonon scattering are thereby caused to reduce thermal conductivity of the thermoelectric body. Electric conductivity of the thermoelectric body is substantially increased by doping the thermoelectric body with a dopant. In an embodiment of a thermoelectric device, when there is no temperature difference between a first region and a second region, a temperature difference may be generated by supplying power from an external power source. In such an embodiment, the thermoelectric device may function as a cooler.

As described above, according to the one or more of the above embodiments of the present disclosure, the thermoelectric properties of a thermoelectric device may be substantially improved by forming a thermoelectric device including a vacancy cluster formed therein. In addition, since the thermoelectric body includes Si, or the like, the thermoelectric body may be mass-produced with substantially reduced manufacturing costs, and may be easily applied to other devices.

It should be understood that the exemplary embodiments described herein should be considered in a descriptive sense only and not for purposes of limitation. Descriptions of features or aspects within each embodiment should typically be considered as available for other similar features or aspects in other embodiments.

What is claimed is:

1. A thermoelectric device comprising:
a first region;
a second region; and
a thermoelectric body disposed between the first region and the second region,
wherein the thermoelectric body comprises a vacancy.

2. The thermoelectric device of claim 1, wherein the thermoelectric body comprises silicon (Si).

3. The thermoelectric device of claim 1, wherein the thermoelectric body comprises at least one of amorphous silicon and polysilicon.

4. The thermoelectric device of claim 1, wherein the thermoelectric body comprises at least one of glass, germanium (Ge), SiGe, sapphire, quartz and an organic material.

5. The thermoelectric device of claim 1, wherein the thermoelectric body comprises at least one of an n-type dopant and a p-type dopant.

6. The thermoelectric device of claim 5, wherein the at least one of the n-type dopant and the p-type dopant comprises at least one of arsenic (As), phosphorus (P), boron (B), aluminium (Al), gallium (Ga), antimony (Sb), indium (In) and silicon (Si).

7. The thermoelectric device of claim 1, further comprising:
a first electrode disposed between the first region and the thermoelectric body; and
a second electrode disposed between the second region and the thermoelectric body.

8. A thermoelectric device array comprising:
a plurality of first regions;
a plurality of second regions; and
a plurality of thermoelectric bodies,
wherein the plurality of thermoelectric bodies comprises:
a plurality of first thermoelectric bodies doped with an n-type dopant; and
a plurality of second thermoelectric bodies doped with a p-type dopant,
wherein the plurality of first thermoelectric bodies and the plurality of
second thermoelectric bodies are alternately disposed between the plurality of
first regions and the plurality of second regions, and
wherein the plurality of thermoelectric bodies comprises a plurality of vacancies formed therein.

9. The thermoelectric device array of claim 8, wherein each of the plurality of thermoelectric bodies comprise silicon (Si).

10. The thermoelectric device array of claim 8, wherein each of the plurality of thermoelectric bodies comprises at least one of amorphous silicon and polysilicon.

11. The thermoelectric device array of claim 8, wherein each of the thermoelectric bodies comprises at least one of glass, germanium (Ge), SiGe, sapphire, quartz and an organic material.

12. The thermoelectric device array of claim 8, wherein at least one of the n-type dopant and the p-type dopant comprises at least one of arsenic (As), phosphorus (P), boron (B), aluminium (Al), gallium (Ga), antimony (Sb), indium (In) and silicon (Si).

13. A method of preparing a thermoelectric body of a thermoelectric device, the method comprising:
forming a plurality of vacancies in the thermoelectric body by doping the thermoelectric body with at least one of an n-type dopant and a p-type dopant,
wherein the at least one of the n-type dopant and the p-type dopant has a high concentration equal to or greater than 10¹⁸ atoms per cubed centimeter.

14. The method of claim 13, further comprising:
activating the at least one of the n-type dopant and the p-type dopant using a heat-treatment process.
